(19) United States
(12) Patent Application Publication
(10) Pub. No.: US 2025/0251352 A1
(43) Pub. Date: Aug. 7, 2025

(54) VIA DETECTION DEVICE AND METHOD FOR THROUGH GLASS VIA SUBSTRATE

(71) Applicants: KUN-HSIEN CHENG, Taoyuan City (TW); Shyawei Optronics Corporation, Taoyuan City (TW)

(72) Inventor: KUN-HSIEN CHENG, Taoyuan City (TW)

(21) Appl. No.: 18/812,128

(22) Filed: Aug. 22, 2024

(30) Foreign Application Priority Data
Feb. 6, 2024 (TW) 113104788
Mar. 29, 2024 (TW) 113112184
Jul. 19, 2024 (TW) 113127128

(51) Int. Cl. G01N 21/95; G01N 21/88; H01L 23/15; H01L 23/498

(52) U.S. Cl. CPC G01N 21/9501; G01N 21/8851; H01L 23/15; H01L 23/49827

(57) ABSTRACT

A via detection device for a TGV glass substrate having following components is illustrated. A first DOF camera and a first collimated light source orthogonally face an upper surface of the glass substrate. A second DOF camera and a second collimated light source orthogonally face a lower surface of the glass substrate. The first and second collimated light sources respectively emit a first and second collimated beams to the glass substrate. An optical band of the first collimated beam is different from or identical to an optical band of the second collimated beam. The first DOF camera and the second DOF camera are respectively configured to obtain a first image and a second image, and the microcontroller unit of the TGV glass substrate is configured to obtain at least one detection result of the at least one glass substrate via according to the first image and the second image.

### BACKGROUND

### Technical Field

The present disclosure relates to a via detection device and via detection method for a through glass via (TGV) glass substrate, and more particularly, to the via detection device and method for the TGV glass substrate that adopt two depth-of-field (DOF) cameras and two collimated light sources located above and below the glass substrate to obtain a detection result of the TGV glass substrate.

### Related Art

As conventional two-dimensional (2D) chip packaging techniques no longer meet the current requirements for speeds, performances and thinness of chips, two point five-dimensional (2.5D) and three-dimensional (3D) chip packaging techniques have been proposed. Both the 2.5D and 3D chip packaging techniques require interposers with vias to electrically connect different chips. In conventional techniques, a silicon substrate with through silicon vias (TSVs) (also known as TSV glass substrate) is used as the interposer. However, silicon is IV-A semiconductor material, and thus the surrounding carriers can move freely under the effects of electric or magnetic fields, such that the surrounding carriers which can move freely affect the adjacent circuits or signals, or even affect the performances of the chips. However, as the glass material has no freely moving charges, and also has an excellent dielectric performance and a coefficient of thermal expansion (CTE) which is close to a CTE of the silicon. Therefore, the glass substrate with through glass vias (TGVs) (also known as TGV glass substrate) is proposed to replace the TSV glass substrates as the interposer.

The method of manufacturing the glass substrate with the glass substrate vias is to irradiate laser at predetermined positions where the glass substrate vias are to be formed to modify material properties of the predetermined positions of the glass substrate, and then use immersion etching to form the glass substrate vias at the predetermined positions. Referring to FIG. 1 and FIG. 2, FIG. 1 shows a top view of a glass substrate with glass substrate vias, and FIG. 2 shows a perspective view along a cross-section line A-A in FIG. 1. The glass substrate 1 has a plurality of glass substrate vias 12 penetrating through the upper surface 10 and the lower surface 12 of the glass substrate 1. Each glass substrate via 12 has an upper opening 121 on the upper surface 10 and a lower opening 123 on the lower surface 11, and has a waist between the upper surface 10 and the lower surface 11, and the waist forms the via 122. The upper opening 121 and the lower opening 123 have diameters Rt and Rb respectively, and the via 122 of the waist forms the via diameter Rm.

Parameter information such as the opening diameters Rt, Rb and the via diameter Rm must be detected so as to evaluate whether the glass substrate 1 meets the requirements or not. One conventional solution is to use the X-ray to detect the glass substrate 1, but the detection speed of the X-ray is too slow (even slower than using a microscope), thus failing to meet the production benefits. In addition, using a microscope for detection as another conventional solution is still very time-consuming, and therefore also fails to meet the financial benefits. Yet another conventional solution is to fill the glass substrate via 12 with lossless plastic material, and then take out the lossless plastic material for measuring the above information. However, the above manner requires filling the lossless plastic material which causes extra cost and extra detection time, and may also face the problem that the lossless plastic material remains in the glass substrate via 12. In view of this, it is necessary to propose a novel glass substrate via detection approach to avoid the above technical problems.

### SUMMARY

According to any of the above objectives, the present disclosure provides a via detection device for a through glass via (TGV) glass substrate, which comprises a first depth-of-field (DOF) camera, a first collimated light source, a second DOF camera, a second collimated light source and a microcontroller unit. The first DOF camera and the first collimated light source are arranged on a glass substrate with at least one glass substrate via, and orthogonally face an upper surface of the glass substrate. The second DOF camera and the second collimated light source are arranged below the glass substrate, and orthogonally face a lower surface of the glass substrate. The microcontroller unit is electrically connected with the first DOF camera, the first collimated light source, the second DOF camera and the second collimated light source. The first collimated light source and the second collimated light source respectively emit a first collimated beam and a second collimated beam to the glass substrate, and an optical band of the first collimated beam is different from or identical to an optical band of the second collimated beam. The first DOF camera and the second DOF camera are respectively configured to obtain a first image and a second image, and the microcontroller unit is configured to obtain at least one detection result of the at least one glass substrate via according to the first image and the second image.

According to any of the above objectives, the present disclosure provides a via detection device for a through glass via (TGV) glass substrate, which comprises a first DOF camera, a first collimated light source, a second DOF camera, a second collimated light source, a beam-splitting prism module, a third DPF camera and a microcontroller unit. The first DOF and the first collimated light source are arranged on a glass substrate with at least one glass substrate via, and orthogonally face an upper surface of the glass substrate. The second DOF and the second collimated light source are arranged below the glass substrate, and orthogonally face a lower surface of the glass substrate. he microcontroller unit is electrically connected with the first DOF camera, the first collimated light source, the second DOF camera, the second collimated light source and the third DOF camera. The beam-splitting prism module is arranged between the upper surface of the glass substrate and the first collimated light source. The third DOF camera is arranged on a side of the beam-splitting prism module. The first collimated light source and the second collimated light source respectively emit a first collimated beam and a second collimated beam to the glass substrate, and the beam-splitting prism module splits the first collimated beam emitted to the glass substrate from the first collimated light source, the first collimated beam reflected by the glass substrate and the second collimated beam passes through the glass substrate. A split portion of the second collimated beam passing through the glass substrate and a split portion of the first collimated beam emitted to the glass substrate from the first collimated light source and a split portion of the first collimated beam reflected by the glass substrate are received by the third DOF camera. Another split portion of the second collimated beam passing through the glass substrate and another split portion of the first collimated beam reflected by the glass substrate are received by the first DOF camera, and another split portion of the first collimated beam emitted to the glass substrate from the first collimated light source partially passes through the glass substrate and is partially reflected by the glass substrate. An optical band of the first collimated beam is different from or identical to an optical band of the second collimated beam. The first DOF camera, the second DOF camera and the third DOF camera are respectively configured to obtain a first image, a second image and a third image, and the microcontroller unit is configured to obtain at least one detection result of the at least one glass substrate via according to the first image, the second image and the third image.

Based on the above purpose, the present disclosure also provides a via detection method for a TGV glass substrate, which is executed by a via detection device of the TGV glass substrate. The via detection device comprises a first DOF camera, a first collimated light source, a second DOF camera and a second collimated light source. The first DOF camera and the first collimated light source are arranged on a glass substrate with at least one glass substrate via, and orthogonally face an upper surface of the glass substrate. The second DOF camera and the second collimated light source are arranged below the glass substrate, and orthogonally face a lower surface of the glass substrate. The via detection method comprises: controlling, by a microcontroller unit of the via detection device for the TGV glass substrate, the first DOF camera, the first collimated light source, the second DOF camera and the second collimated light source so that the first collimated light source and the second collimated light source respectively emit a first collimated beam and a second collimated beam to the glass substrate, and the first DOF camera and the second DOF camera respectively obtain a first image and a second image, wherein an optical band of the first collimated beam is different from or identical to an optical band of the second collimated beam; and obtaining, by the microcontroller unit of the via detection device for the TGV glass substrate, at least one detection result of the at least one glass substrate via according to the first image and the second image.

To summarize, the present disclosure provides a via detection device and method for a through glass via (TGV) glass substrate adopting an optical detection manner without filling lossless molding materials, therefore not only reducing the detection time and cost, but also avoiding the damage of the glass substrate.

### DESCRIPTIONS OF DRAWINGS

FIG. 1 shows a top view of a glass substrate with glass substrate vias.

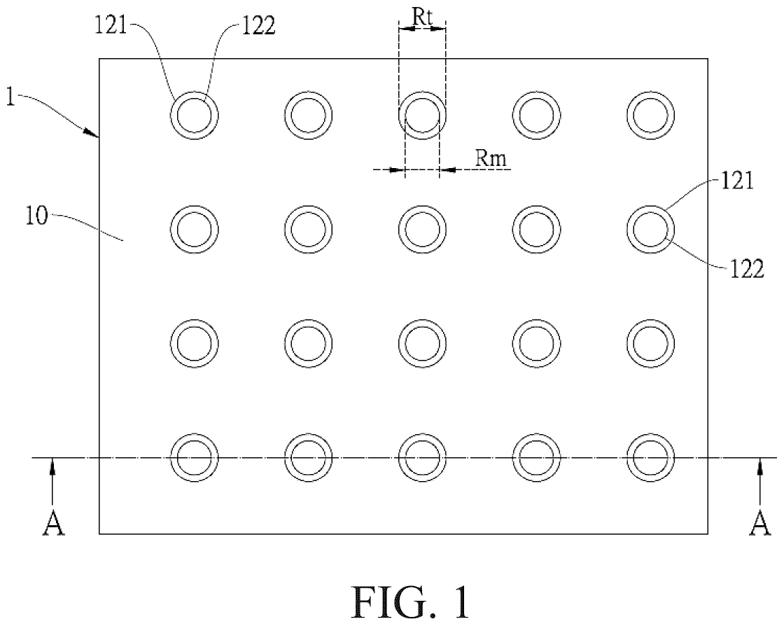

FIG. 2 shows a perspective view along the cross-section line in FIG. 1.

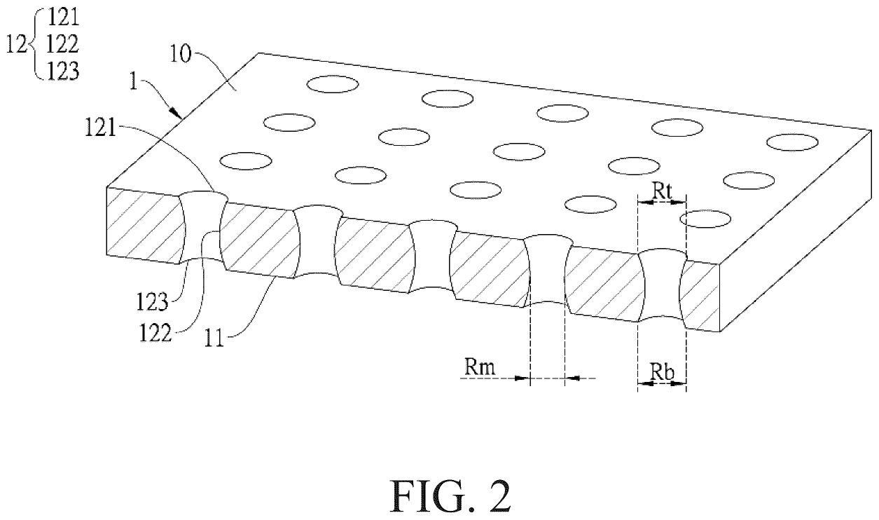

FIG. 3 is a diagram illustrating a schematic plan view of a scenario which a glass substrate is detected by a via detection device for a TGV glass substrate according to an embodiment of the present disclosure.

FIG. 4 is a diagram illustrating a schematic cross-sectional view of a scenario which the glass substrate is detected by the via detection device for the TGV glass substrate according to an embodiment of the present disclosure, in which the cross-section of the glass substrate is along the cross-section line in FIG. 3.

FIG. 5 a diagram illustrating the first DOF camera and the first collimated light source implemented by the first telecentric lens imaging module according to an embodiment of the present disclosure.

FIG. 6 is a diagram illustrating a first image and a second image according to an embodiment of the present disclosure,

FIG. 7 shows defects of different types that can be detected by the via detection device for the TGV glass substrate according to an embodiment of the present disclosure.

FIG. 8A is a diagram illustrating a perspective view of a part of the structure of the via detection device for the TGV glass substrate according to an embodiment of the present disclosure.

FIG. 8B is a diagram illustrating a front view of a part of the structure of the via detection device for the TGV glass substrate according to an embodiment of the present disclosure.

FIG. 8C is a diagram illustrating a side view of a part of the structure of the via detection device for the TGV glass substrate according to an embodiment of the present disclosure.

FIG. 9 is a diagram illustrating a schematic cross-sectional view of a scenario which the glass substrate is detected by the via detection device for the TGV glass substrate according to another embodiment of the present disclosure.

### DESCRIPTIONS OF EMBODIMENTS

In order to facilitate understanding of the technical features, advantages and technical effects of the present disclosure during examination, the present disclosure is illustrated in detail in the form of examples with the accompanying drawings. The drawings used herein are only for illustrative and auxiliary purposes, and the contents thereof may not be shown in the exact ratio and configuration. Hence, it should be noted that the shown ratios and configurations shall not be used to limit the scope of the present disclosure.

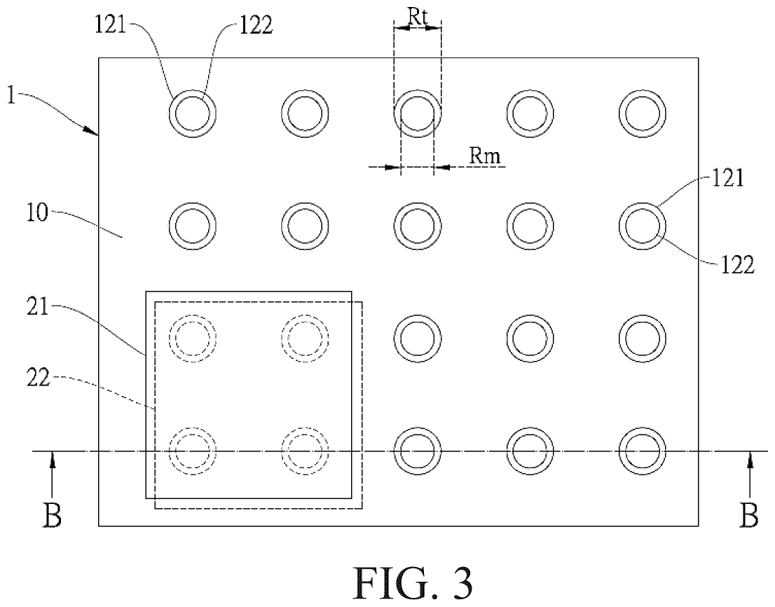

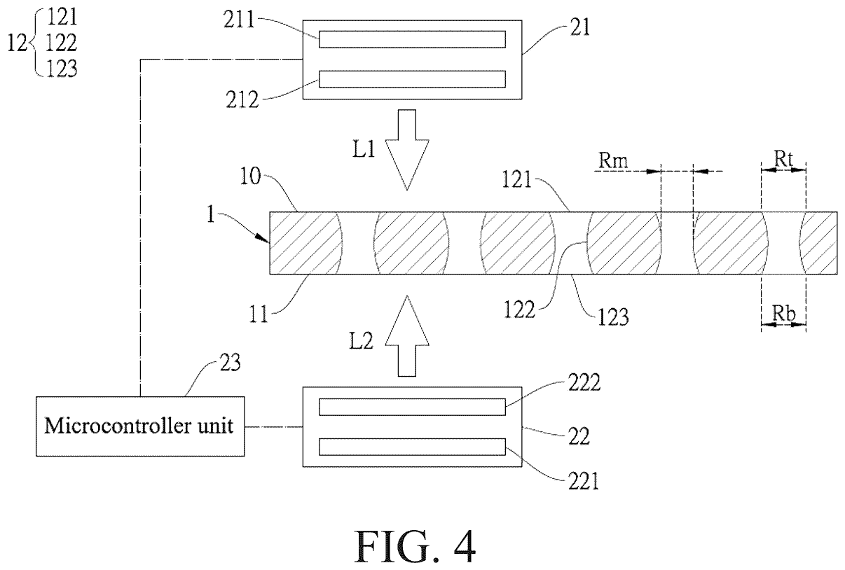

Please refer to FIG. 3 and FIG. 4. FIG. 3 is a diagram illustrating a schematic plan view of a scenario which a glass substrate is detected by a via detection device for a TGV glass substrate according to an embodiment of the present disclosure, and FIG. 4 is a diagram illustrating a schematic cross-sectional view of a scenario which the glass substrate is detected by the via detection device for the TGV glass substrate according to an embodiment of the present disclosure, in which the cross-section of the glass substrate is along the cross-section line in FIG. 3, in which the cross-section of the glass substrate is along the cross-section line B-B in FIG. 3. The via detection device for the TGV glass substrate comprises a first DOF camera 211, a first collimated light source 212, a second DOF camera 221, a second collimated light source 222 and a microcontroller unit 23. The first DOF camera 211 and the first collimated light source 212 can be integrated into a first telecentric lens imaging module 21 (e.g., a telecentric camera), and the second DOF camera 221 and the second collimated light source 222 can be integrated into a second telecentric lens imaging module 22, but the present disclosure is not limited thereto.

The first DOF camera 211 and the first collimated light source 212 are arranged on the glass substrate 1 with at least one glass substrate via 12, and orthogonally face the upper surface 10 of the glass substrate 1. More specifically, the first DOF camera 211 and the first collimated light source 212 orthogonally facing the upper surface 10 refers to that both the extension directions of the image capturing end of the first DOF camera 211 and the emitting end of the first collimated light source 212 are perpendicular to the upper surface 10 of the glass substrate 1. The second DOF camera 221 and the second collimated light source 222 are arranged below the glass substrate 1 and orthogonally face the lower surface 11 of the glass substrate 1. More specifically, the second DOF camera 221 and the second collimated light source 222 orthogonally facing the lower surface 11 of the glass substrate 1 refers to that both the extension directions of the imaging end of the second DOF camera 221 and the emitting end of the second collimated light source 222 are perpendicular to the lower surface 11 of the glass substrate 1.

The microcontroller unit 23 is electrically connected with the first DOF camera 211, the first collimated light source 212, the second DOF camera 221 and the second collimated light source 222, and the first DOF camera 211, the first collimated light source 212, the second DOF camera 221 and the second collimated light source 222 are controlled by the microcontroller unit 23. The microcontroller unit 23 controls the first collimated light source 212 and the second collimated light source 222 to emit the first collimated beam L1 and the second collimated beam L2 to the glass substrate 1, respectively. The optical band of the first collimated beam L1 is different from or identical to the optical band of the second collimated beam L2, which means that the color of the first collimated beam L1 is different from or identical to the color of the second collimated beam L2. For example, each of the color of the first collimated beam L1 and the color of the second collimated beam L2 is selected from red, green, blue and white. In addition, the collimation of the first collimated beam L1 and the second collimated beam L2 is related to the depth of the glass substrate via 12, i.e., the thickness of the glass substrate 1. Further, according to the actual situation, the first DOF camera 211 and the second DOF camera 221 can be black and white cameras or color cameras.

After the first collimated beam L1 and the second collimated beam L2 are emitted to the glass substrate 1, the second sensing beam and the first sensing beam are respectively generated for the first DOF camera 211 and the second DOF camera 221, so that the first DOF camera 211 and the second DOF camera 221 can obtain the first image and the second image accordingly. Next, the microcontroller unit 23 is used to obtain at least one detection result of at least one glass substrate via 12 according to the first image and the second image. In addition, the maximum detectable depths of the first DOF camera 211 and the second DOF camera 221 are related to the depth of the glass substrate via 12, that is, the thickness of the glass substrate 1.

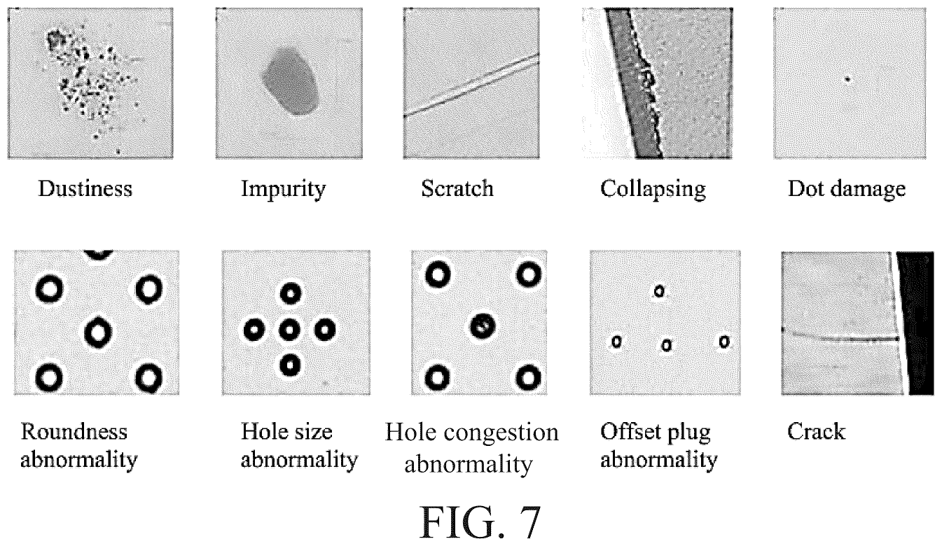

Further, referring to FIG. 3, FIG. 4 and FIG. 7, the detection result can comprise at least one of the opening diameter Rt of the upper opening 121 of the glass substrate via 12, the opening diameter Rb of the lower opening 123 of the glass substrate via 12 (p.s. the opening diameters Rt, Rb can be used to determine whether there is abnormality in hole sizes), an opening coordinate of the upper opening 121 or the lower opening 123, an opening roundness of the upper opening 121 or the lower opening 123 (which can be used to determine whether there is abnormality in roundness), a crack detection result, a dustiness detection result, a dot damage detection result, a scratch detection result, an impurity detection result, an edge collapse detection result, a via diameter Rm of the glass substrate via 12 (i.e., the diameter of the via 122 of the waist of the glass substrate via 12), a hole congestion detection result (which can be used to determine whether there is abnormality due to the congestion of the hole) and an offset amount between upper and lower openings (which can be used to determine whether there is abnormality in offset) of the glass substrate via 12.

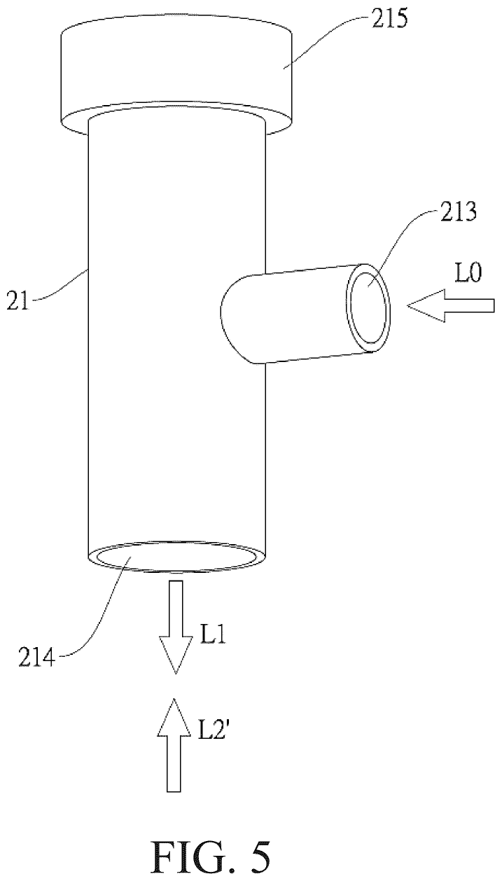

Next, please refer to FIG. 5, which is a diagram illustrating the first DOF camera and the first collimated light source implemented by the first telecentric lens imaging module according to an embodiment of the present disclosure. The first telecentric lens imaging module 21 comprises a light receiving lens module 213, a telecentric lens module 214 and an imaging module 215. The first telecentric lens imaging module 21 is in a T-shape, in which the imaging module 215 is arranged at the top of the first telecentric lens imaging module 21, the light receiving lens module 213 is arranged at a side of the first telecentric lens imaging module 21, and the telecentric lens module 214 is arranged at the bottom of the first telecentric lens imaging module 21. The light receiving lens module 213 receives the beam L0 of the initial light source, the telecentric lens module 214 is configured to emit the first collimated beam L1 and receive the first sensing beam L2′ (which is generated by irradiating the second collimated beam L2 to the glass substrate 1), and the imaging module 215 is configured to generate the first image according to the first sensing beam L2′.

Furthermore, similar to FIG. 5, the second telecentric lens imaging module 22 of FIG. 4 comprises another light receiving lens module, another telecentric lens module and another imaging module. The second telecentric lens imaging module 22 has a T-shape. The other imaging module is arranged at the top of the of the second telecentric lens imaging module 22, the other light receiving lens module is arranged at a side of the second telecentric lens imaging module 22, and the telecentric lens module is arranged at the bottom of the second telecentric lens imaging module 22. Another light receiving lens module receives the beam of another initial light source, another telecentric lens module is configured to emit a second collimated beam L2 and receive a second sensing beam (which is generated by irradiating the first collimated beam L1 to the glass substrate 1), and another imaging module is configured to generate a second image according to the second sensing beam.

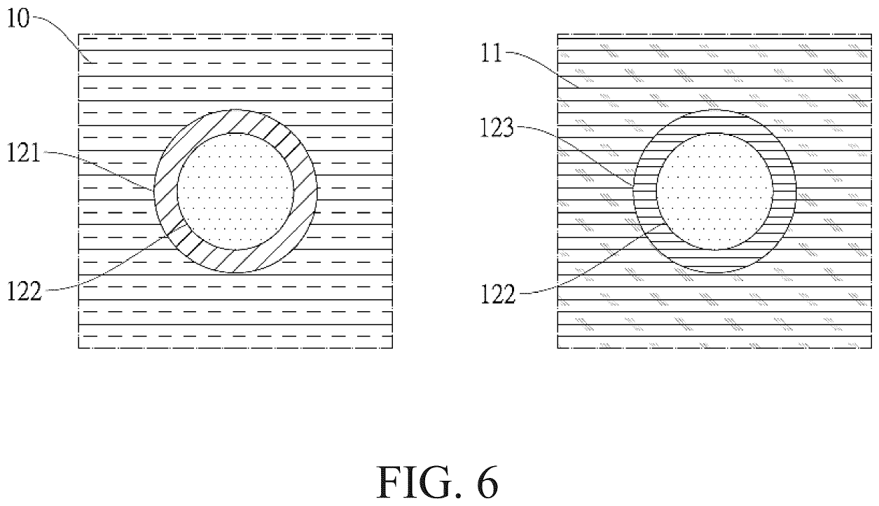

Please refer to FIG. 6, which is a diagram illustrating a first image and a second image according to an embodiment of the present disclosure, wherein the left side of FIG. 6 shows the first image, and the right side of FIG. 6 shows the second image. The first image presents an image of the upper opening 121 of the at least one glass substrate via 12, the via 122 of the waist of the at least one glass substrate via 12 and a part of the upper surface 10 of the glass substrate 1 near the upper opening 121, wherein the color of the via 122 is the color of the second collimated beam L2, the color from the upper opening 121 to the via 122 is black, and the color of the part of the upper surface 10 of the glass substrate 1 near the upper opening 121 is a mixed color of the color of the first collimated beam L1 and the color of the second collimated beam L2.

The second image presents an image of at least one lower opening 123 of the glass substrate via 12, and a via 122 of the waist of the glass substrate via 12 and a part of the lower surface 11 of the glass substrate 1 near the lower opening 123, wherein the color of the via 122 is the color of the first collimated beam L1, the color from a lower opening 123 to a via 122 is black, and the color of the part of the lower surface 11 of the glass substrate 1 near the lower opening 123 is a mixed color of the color of the first collimated beam L1 and the color of the second collimated beam L2.

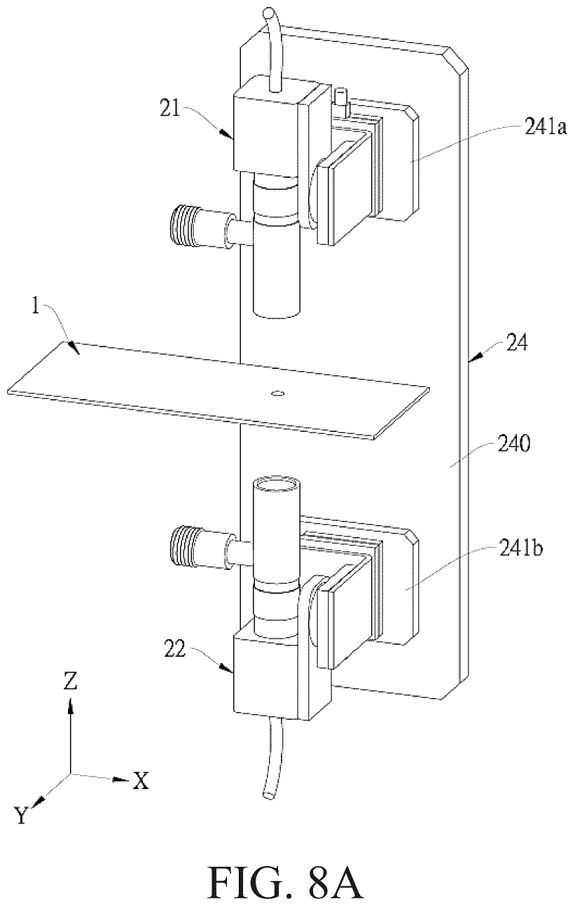

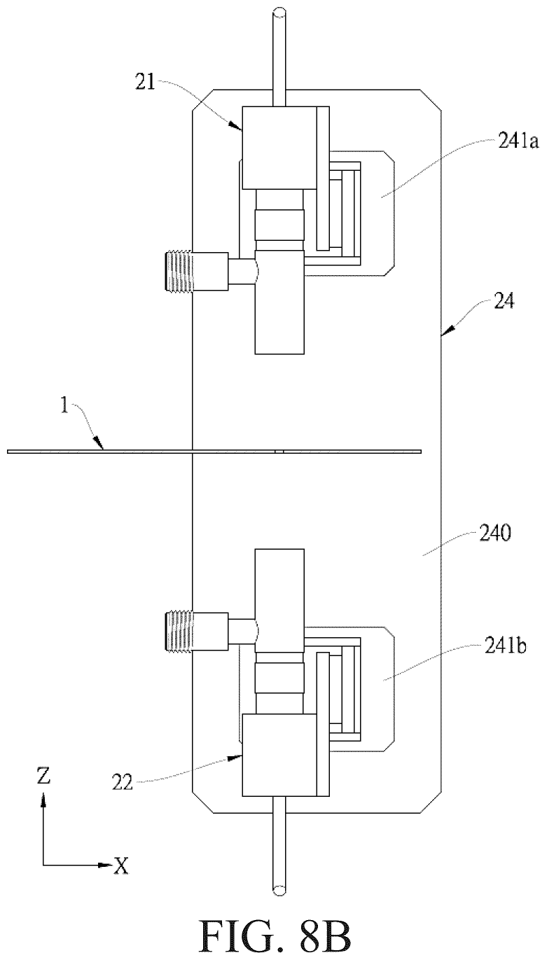

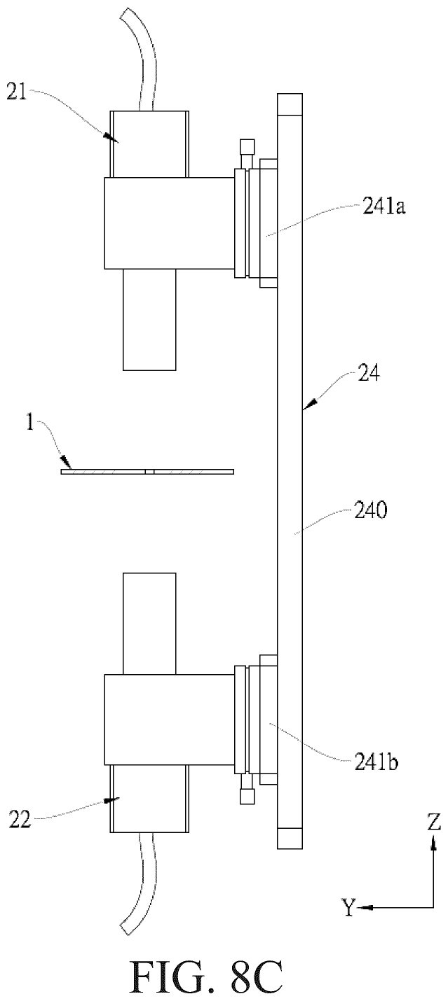

Further, the via detection device for the TGV glass substrate further comprises a main frame body (not shown) and a glass substrate supporting structure (not shown). The glass substrate supporting structure is arranged in the main frame body for contacting at least a part of the glass substrate 1 (e.g., the four corners thereof, but the present disclosure is not limited thereto) to support the glass substrate 1. In addition, please refer to FIG. 8A to FIG. 8C. FIG. 8A is a diagram illustrating a perspective view of a part of the structure of a via detection device for the TGV glass substrate according to an embodiment of the present disclosure, FIG. 8B is a diagram illustrating a front view of a part of the structure of the via detection device for the TGV glass substrate according to an embodiment of the present disclosure, and FIG. 8C is a diagram illustrating a side view of a part of the structure of the via detection device for the TGV glass substrate according to an embodiment of the present disclosure. In addition to the main frame body (not shown) and the glass substrate supporting structure (not shown), the via detection device for the TGV glass substrate further comprises a base structure 24 for supporting and fixing the first telecentric lens imaging module 21 and the second telecentric lens imaging module 22, wherein the base structure 24 comprises a common base 240, a first base 241a and a second base 241b, and the first base 241a and the second base 241b are arranged on the opposite sides of the common base 240, and are respectively used to support and fix the first telecentric imaging modules 21 and the second telecentric imaging modules 22.

In one embodiment, if the size of the glass substrate 1 is not relatively large, the first telecentric lens imaging module 21 and the second telecentric lens imaging module 22 can obtain the first and second images of the complete glass substrate 1 without moving. In this way, the common base 240 can be fixed in the main frame body, and the glass substrate supporting structure is also fixed in the main frame body, and the glass substrate 1 will not move relative to the first telecentric lens imaging module 21 and the second telecentric lens imaging module 22. If the size of the glass substrate 1 is too large, the first telecentric lens imaging module 21 and the second telecentric lens imaging module 22 must move to obtain the first and second images of the complete glass substrate 1. In this way, the common base 240 can be arranged to be fixed in the main frame body, and the glass substrate supporting structure is movably arranged in the main frame body; or otherwise the common base 240 is arranged movably in the main frame body, while the glass substrate supporting structure is arranged to be fixed in the main frame body. Further, the via detection device for the TGV glass substrate further comprises a transmission mechanism for connecting and moving one of the common base 240 or the glass substrate supporting structure, so that the glass substrate 1 can move relative to the first telecentric lens imaging module 21 and the second telecentric lens imaging module 22.

In addition, each of the first base 241a and the second base 241b comprises an adjusting structure. For example, rather than limitation, the adjusting structure can comprise an adjusting washer, an adjustment screw, an adjusting bearing or one other adjusting part. The adjusting structure of the first base 241a and the second base 241b can be used to adjust the offset of the first telecentric lens imaging module 21 and the second telecentric lens imaging module 22, respectively. The aforementioned offset may be the offset in both X and Y axes, or in X, Y and Z axes, but the present disclosure does not limit the way of carrying out the adjusting structure. In addition, as can be seen from the above in the present disclosure, when the first telecentric lens imaging module 21 and the second telecentric lens imaging module 22 need to move relative to the glass substrate 1, the first telecentric lens imaging module 21 and the second telecentric lens imaging module 22 are designed to move relative to the glass substrate 1 in a linked manner. This provides the advantage that once the adjustment of the offset is done, it can be avoided the offset (which requires readjustment) caused by that one of the first telecentric lens imaging module 21 and the second telecentric lens imaging module 22 move alone. Hence, the present disclosure can improve the measurement accuracy, or reduce the time and labor cost on adjusting the offset.

Furthermore, based on the above concepts, the present disclosure also provides a via detection method for a TGV glass substrate, which is executed by a via detection device for TGV glass substrate, and the via detection device comprises a first DOF camera, a first collimated light source, a second DOF camera and a second collimated light source. The first DOF camera and the first collimated light source are arranged on a glass substrate with at least one glass substrate via, and orthogonally face an upper surface of the glass substrate. The second DOF camera and the second collimated light source are arranged below the glass substrate, and orthogonally face a lower surface of the glass substrate. The via detection method comprises: controlling, by a microcontroller unit of the via detection device for the TGV glass substrate, the first DOF camera, the first collimated light source, the second DOF camera and the second collimated light source so that the first collimated light source and the second collimated light source respectively emit a first collimated beam and a second collimated beam to the glass substrate, and the first DOF camera and the second DOF camera respectively obtain a first image and a second image, wherein an optical band of the first collimated beam is different from or identical to an optical band of the second collimated beam; and obtaining, by the microcontroller unit of the via detection device for the TGV glass substrate, at least one detection result of the at least one glass substrate via according to the first image and the second image.

In addition, when the size of the glass substrate is relatively larger, the first telecentric lens imaging module and the second telecentric lens imaging module must move to obtain the first image and the second image of the complete glass substrate, the via detection method further comprises: making the first DOF camera, the first collimated light source, the second DOF camera and the second collimated light source of the via detection device for TGV glass substrate move relative to the glass substrate (i.e. the first DOF camera, the first collimated light source, the second DOF camera and the second collimated light source move altogether while the glass substrate remains still, or the first DOF camera, the first collimated light source, the second DOF camera and the second collimated light source remains still while the glass substrate moves).

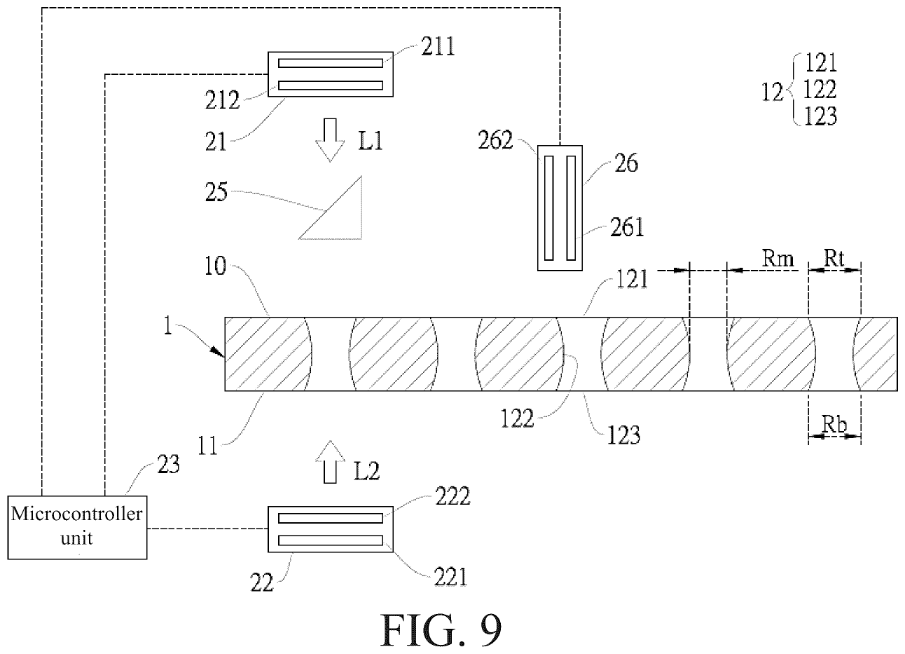

Refer to FIG. 9, and FIG. 9 is a diagram illustrating a schematic cross-sectional view of a scenario which the glass substrate is detected by the via detection device for the TGV glass substrate according to another embodiment of the present disclosure. Being different from the embodiment of FIG. 4, in the embodiment of FIG. 9, the via detection device further comprises a beam-splitting prism module 25 and a third telecentric lens imaging module 26, wherein the beam-splitting prism module 25 is arranged between the upper surface 10 of the glass substrate 1 and the first telecentric lens imaging module 21, and the third telecentric lens imaging module 26 is arranged on a side of the beam-splitting prism module 25, such as the right side of the beam-splitting prism module 25. The third telecentric lens imaging module 26 comprises a third DOF camera 261 and a third collimated light source 262, but the third collimated light source 262 in the embodiment is disabled and cannot emit a third collimated light beam. The third DOF camera 261 is electrically connected with the microcontroller unit 23. The second collimated light beam L2 straightly passes through the glass substrate 1, wherein the second collimated light beam L2 passes through the via 122 and the part of the glass substrate 121 outside the upper opening 121 (if the opening diameter Rt of the upper opening 121 is larger than or equal to the opening diameter Rm of the lower opening 123), or alternatively, the second collimated light beam L2 passes through the via 122 and the part of the glass substrate 121 outside the lower opening 123 (if the opening diameter Rt of the upper opening 121 is less than the opening diameter Rm of the lower opening 121). The beam-splitting prism module 25 can be formed by at least optical component, such as a prism, but the present disclosure is not limited thereto, for example, the beam-splitting prism module 25 is formed by a beam-splitting prism and at least one mirror. The beam-splitting prism module 25 splits the second collimated beam L2 passing through the glass substrate 1, and further splits the first collimated beam L1 emitted to the glass substrate 1 from the first collimated light source 212 and the first collimated beam L1 reflected by the glass substrate 1.

A split portion of the second collimated beam L2 passing through the glass substrate 1, a split portion of the first collimated beam L1 emitted to the glass substrate 1 from the first collimated light source 212 and a split portion of the first collimated beam L1 reflected by the glass substrate 1 are received by the third DOF camera 261, and thus the third DOF camera 261 accordingly obtains a third image. Another split portion of the second collimated beam L2 passing through the glass substrate 1 and another split portion of the first collimated beam L1 reflected by the glass substrate 1 are received by the first DOF camera 211, and the first DOF camera 211 accordingly obtains a first image. The brightness of the third image is thus larger the brightness of the first image, or the color of third image is more closed the color of the first collimated beam L1 while compared to the first image. Another split portion of the first collimated beam L1 emitted to the glass substrate 1 from the first collimated light source 212 is partially reflected by the glass substrate 1 and partially passing through the glass substrate 1. The second DOF camera 221 receives the first collimated light beam L1 passing through the glass substrate 1 and the second collimated light beam L2 reflected by the glass substrate 1, and the second DOF camera 221 accordingly obtains a second image.

In the embodiment, the via detection device can obtain the more accurate detection result of the glass substrate via 12 according to the first image, the second image and the third image. Furthermore, in the embodiment, the color of the first collimated beam L1 can be different from or identical to the color of the second collimated beam L2. For example, each of the color of the first collimated beam L1 and the color of the second collimated beam L2 can be selected from white, red, green or blue. Moreover, according to the actual situation, the first DOF camera 211, the second DOF camera 221 and the third DOF camera 261 can be black and white cameras or color cameras.

To sum up, the present disclosure provides a via detection device and method for a through glass via (TGV) glass substrate adopting an optical detection manner without filling lossless molding materials, which can detect at least one of the opening diameter of the upper opening of the glass substrate via, the opening diameter of the lower opening of the glass substrate via, an opening coordinate, an opening roundness, a crack detection result, a dustiness detection result, a dot damage detection result, a scratch detection result, an impurity detection result, an edge collapse detection result, a via diameter of the waist of the glass substrate via, a hole congestion detection result and an offset amount between the upper and lower openings of the glass substrate via. Furthermore, the via detection device and method for the TGV glass substrate can not only reduce the detection time and cost, but also avoid the damage of the glass substrate.

The above-mentioned embodiments are only for explaining the technical concepts and characteristics of the present disclosure, and the objective thereof is to make one skilled in the art understand the content of the present disclosure and implement it accordingly, rather than limiting the claimed scope of the present disclosure. That is, all equivalent changes or modifications made in accordance with the spirit of the present disclosure shall fall within the scope of the present disclosure.

1. A via detection device for a through glass via (TGV) glass substrate, comprising:
a first depth-of-field (DOF) camera and a first collimated light source arranged on a glass substrate with at least one glass substrate via, and orthogonally facing an upper surface of the glass substrate;
a second DOF camera and a second collimated light source arranged below the glass substrate, and orthogonally facing a lower surface of the glass substrate; and
a microcontroller unit electrically connected with the first DOF camera, the first collimated light source, the second DOF camera and the second collimated light source;
wherein the first collimated light source and the second collimated light source are respectively configured to emit a first collimated beam and a second collimated beam to the glass substrate, an optical band of the first collimated beam is different from or identical to an optical band of the second collimated beam, and the first DOF camera and the second DOF camera are respectively configured to obtain a first image and a second image, and the microcontroller unit is configured to obtain at least one detection result of the at least one glass substrate via according to the first image and the second image.

2. The via detection device for the TGV glass substrate according to claim 1, wherein the detection result comprises at least one of an opening diameter of an upper opening of the glass substrate via, an opening diameter of a lower opening of the glass substrate via, an opening coordinate, an opening roundness, a crack detection result, a dustiness detection result, a dot damage detection result, a scratch detection result, an impurity detection result, an edge collapse detection result, a via diameter of the glass substrate via, a hole congestion detection result and an offset amount between the upper opening and the lower opening of the glass substrate via.

3. The via detection device for the TGV glass substrate according to claim 1, wherein the first DOF camera and the first collimated light source are integrated into a first telecentric lens imaging module; the first telecentric lens imaging module comprises a light receiving lens module, and a telecentric lens module and an imaging module; the first telecentric lens imaging module is in a T-shape, the imaging module is arranged at a top of the first telecentric lens imaging module, the light receiving lens module is arranged at a side of the first telecentric lens imaging module, and the telecentric lens module is arranged at a bottom of the first telecentric lens imaging module; the light receiving lens module receives a beam from an initial light source, the telecentric lens module is configured to emit the first collimated beam and receive a first sensing beam, and the imaging module is configured to generate the first image according to the first sensing beam.

4. The via detection device for the TGV glass substrate according to claim 3, wherein the second DOF camera and the second collimated light source are integrated into a second telecentric lens imaging module; the second telecentric lens imaging module comprises another light receiving lens module, another telecentric lens module and another imaging module; the second telecentric lens imaging module is in a T-shape, the other imaging module is arranged at a top of the second telecentric lens imaging module, the other light receiving lens module is arranged at a side of the second telecentric lens imaging module, and the other telecentric lens module is arranged at a bottom of the second telecentric lens imaging module; the other light receiving lens module receives a beam from another initial light source, and the other telecentric lens module is configured to emit the second collimated beam and receive a second sensing beam, and the other imaging module is configured to generate the second image according to the second sensing beam.

5. The via detection device for the TGV glass substrate according to claim 4, further comprising:
a main frame body; and
a glass substrate supporting structure arranged in the main frame body and configured to contact at least a part of the glass substrate to support the glass substrate.

6. The via detection device for the TGV glass substrate according to claim 5, further comprising:
a base structure comprising a common base, a first base and a second base, wherein the first base and the second base are formed on opposite sides of the common base and are respectively configured to support and fix the first telecentric lens imaging module and the second telecentric lens imaging module, and the common base is arrange in the main frame body.

7. The via detection device for the TGV glass substrate according to claim 6, wherein the common base is fixed in the main frame body, and the glass substrate supporting structure is movably arranged in the main frame body, so that the glass substrate moves relative to the first telecentric lens imaging module and the second telecentric lens imaging module; or the common base is movably arranged in the main frame body, and the glass substrate supporting structure is fixed in the main frame body, so that the glass substrate moves relative to the first telecentric lens imaging module and the second telecentric lens imaging module through the movement of the common base.

8. The via detection device for the TGV glass substrate according to claim 1, wherein each of a color of the first collimated beam and a color of the second collimated beam is selected from red, green, blue and white.

9. The via detection device for the TGV glass substrate according to claim 1, wherein the first image is an image showing an upper opening of the at least one glass substrate via of the glass substrate, a via of a waist of the at least one glass substrate via of the glass substrate, and a part of the upper surface of the glass substrate near the upper opening; a color of the via is a color of the second collimated beam, a color from the upper opening to the via is black, and a color of the part of the upper surface of the glass substrate near the upper opening is a mixed color of a color of the first collimated beam and the color of the second collimated beam.

10. The via detection device for the TGV glass substrate according to claim 1, wherein the second image is an image showing the lower opening of the at least one glass substrate via of the glass substrate, a via of a waist of the at least one glass substrate via of the glass substrate, and a part of the lower surface of the glass substrate near the lower opening; a color of the via is a color of the first collimated beam, a color from the lower opening to the via is black, and a color of the part of the lower surface of the glass substrate near the lower opening is a mixed color of the color of the first collimated beam and a color of the second collimated beam.

11. A via detection device for a through glass via (TGV) glass substrate, comprising:
a first depth-of-field (DOF) camera and a first collimated light source arranged on a glass substrate with at least one glass substrate via, and orthogonally facing an upper surface of the glass substrate;
a second DOF camera and a second collimated light source arranged below the glass substrate, and orthogonally facing a lower surface of the glass substrate;
a microcontroller unit electrically connected with the first DOF camera, the first collimated light source, the second DOF camera and the second collimated light source;
a beam-splitting prism module, arranged between the upper surface of the glass substrate and the first collimated light source; and
a third DPF camera, arranged on a side of the beam-splitting prism module, electrically connected with the microcontroller unit;
wherein the first collimated light source and the second collimated light source are respectively configured to emit a first collimated beam and a second collimated beam to the glass substrate, the beam-splitting prism module splits the first collimated beam emitted to the glass substrate from the first collimated light source, the first collimated beam reflected by the glass substrate and the second collimated beam passes through the glass substrate, a split portion of the second collimated beam passing through the glass substrate and a split portion of the first collimated beam emitted to the glass substrate from the first collimated light source and a split portion of the first collimated beam reflected by the glass substrate are received by the third DOF camera, another split portion of the second collimated beam passing through the glass substrate and another split portion of the first collimated beam reflected by the glass substrate are received by the first DOF camera, another split portion of the first collimated beam emitted to the glass substrate from the first collimated light source partially passes through the glass substrate and is partially reflected by the glass substrate, an optical band of the first collimated beam is different from or identical to an optical band of the second collimated beam, the first DOF camera, the second DOF camera and the third DOF camera are respectively configured to obtain a first image, a second image and a third image, and the microcontroller unit is configured to obtain at least one detection result of the at least one glass substrate via according to the first image, the second image and the third image.

12. The via detection device for the TGV glass substrate according to claim 11, wherein the detection result comprises at least one of an opening diameter of an upper opening of the glass substrate via, an opening diameter of a lower opening of the glass substrate via, an opening coordinate, an opening roundness, a crack detection result, a dustiness detection result, a dot damage detection result, a scratch detection result, an impurity detection result, an edge collapse detection result, a via diameter of the glass substrate via, a hole congestion detection result and an offset amount between the upper opening and the lower opening of the glass substrate via.

13. The via detection device for the TGV glass substrate according to claim 11, wherein each of a color of the first collimated beam and a color of the second collimated beam is selected from red, green, blue and white.

14. The via detection device for the TGV glass substrate according to claim 11, wherein each of the first image and the third image is an image showing an upper opening of the at least one glass substrate via of the glass substrate, a via of a waist of the at least one glass substrate via of the glass substrate, and a part of the upper surface of the glass substrate near the upper opening; a color of the via is a color of the second collimated beam, a color from the upper opening to the via is black, and a color of the part of the upper surface of the glass substrate near the upper opening is a mixed color of a color of the first collimated beam and the color of the second collimated beam.

15. The via detection device for the TGV glass substrate according to claim 11, wherein the second image is an image showing the lower opening of the at least one glass substrate via of the glass substrate, a via of a waist of the at least one glass substrate via of the glass substrate, and a part of the lower surface of the glass substrate near the lower opening; a color of the via is a color of the first collimated beam, a color from the lower opening to the via is black, and a color of the part of the lower surface of the glass substrate near the lower opening is a mixed color of the color of the first collimated beam and a color of the second collimated beam.

16. A via detection method for a through glass via (TGV) glass substrate, being executed by a via detection device of the TGV glass substrate; wherein the via detection device comprises a first depth-of-field (DOF) camera, a first collimated light source, a second DOF camera and a second collimated light source; the first DOF camera and the first collimated light source are arranged on a glass substrate with at least one glass substrate via, and orthogonally face an upper surface of the glass substrate; the second DOF camera and the second collimated light source are arranged below the glass substrate, and orthogonally face a lower surface of the glass substrate; the via detection method comprises:
controlling, by a microcontroller unit of the via detection device for the TGV glass substrate, the first DOF camera, the first collimated light source, the second DOF camera and the second collimated light source so that the first collimated light source and the second collimated light source respectively emit a first collimated beam and a second collimated beam to the glass substrate, and the first DOF camera and the second DOF camera respectively obtain a first image and a second image, wherein an optical band of the first collimated beam is different from or identical to an optical band of the second collimated beam; and
obtaining, by the microcontroller unit of the via detection device for the TGV glass substrate, at least one detection result of the at least one glass substrate via according to the first image and the second image.

17. The via detection method for the TGV glass substrate according to claim 16, wherein the detection result comprises at least one of an opening diameter of an upper opening of the glass substrate via, an opening diameter of a lower opening of the glass substrate via, an opening coordinate, an opening roundness, a crack detection result, a dustiness detection result, a dot damage detection result, a scratch detection result, an impurity detection result, an edge collapse detection result, a via diameter of the glass substrate via, a hole congestion detection result and an offset amount between the upper opening and the lower opening of the glass substrate via.

18. The via detection method for the TGV glass substrate according to claim 16, wherein each a color of the first collimated beam and a color of the second collimated beam is selected from red, green, blue and white.

19. The via detection method for the TGV glass substrate according to claim 16, wherein the first image is an image showing an upper opening of the at least one glass substrate via of the glass substrate, a via of a waist of the at least one glass substrate via of the glass substrate, and a part of the upper surface of the glass substrate near the upper opening; a color of the via is a color of the second collimated beam, a color from the upper opening to the via is black, and a color of the part of the upper surface of the glass substrate near the upper opening is a mixed color of a color of the first collimated beam and the color of the second collimated beam.

20. The via detection method for the TGV glass substrate according to claim 16, wherein the second image is an image showing the lower opening of the at least one glass substrate via of the glass substrate, a via of a waist of the at least one glass substrate via of the glass substrate, and a part of the lower surface of the glass substrate near the lower opening; a color of the via is a color of the first collimated beam, a color from the lower opening to the via is black, and a color of the part of the lower surface of the glass substrate near the lower opening is a mixed color of the color of the first collimated beam and a color of the second collimated beam.
